(19) United States
(12) Patent Application Publication
(10) Pub. No.: US 2024/0206095 A1
(43) Pub. Date: Jun. 20, 2024

(54) ELECTRONIC DEVICE

(71) Applicant: Samsung Display Co., LTD.

(72) Inventors: TAEHYEOG JUNG, Yongin-si (KR); BYUNGHOON KANG, Yongin-si (KR); MIN-HOON CHOI, Yongin-si (KR); SEONGJIN HWANG, Yongin-si (KR)

(21) Appl. No.: 18/367,536

(22) Filed: Sep. 13, 2023

(30) Foreign Application Priority Data
Dec. 20, 2022 (KR) 10-2022-0178838

(51) Int. Cl. H05K 5/03

(52) U.S. Cl. CPC H05K 5/03

(57) ABSTRACT

An electronic device includes a display module including a folding display unit which extends in a first direction and be foldable with reference to a folding axis and a first non-folding display unit and a second non-folding display unit which are spaced apart from each other with the folding display unit therebetween; a support member disposed below the display module, and including a folding part having a plurality of patterns defined therein and corresponding to the folding display unit and a first non-folding part and a second non-folding part respectively corresponding to the first non-folding display unit and the second non-folding display unit; and an adhesive layer disposed between the display module and the support member. The adhesive layer has a modulus of about 1 megapascal (MPa) to about 1500 MPa at −20 degrees Celsius) (° C.).

This application claims priority to Korean Patent Application No. 10-2022-0178838, filed on Dec. 20, 2022, and all the benefits accruing therefrom under 35 U.S.C. § 119, the content of which in its entirety is herein incorporated by reference.

### BACKGROUND

### 1. Field

The disclosure herein relates to a window and an electronic device including the same, and more particularly, to a foldable window and an electronic device including the same.

### 2. Description of the Related Art

Various types of electronic devices are used for providing image information, and recently, display devices including a flexible display panel which is foldable or bendable are being developed. Unlike a rigid display device, a flexible display device is foldable, rollable, bendable, and the like, that is, deformable into various shapes, and thus has a property which is portable regardless of a display screen size.

It is desired for such a flexible display device to have a structure for protecting a display panel without causing deterioration in a folding or bending operation.

### SUMMARY

The disclosure provides an electronic device having a favorable folding property and a relatively high impact resistance.

An embodiment of the inventive concept provides an electronic device including: a display module including a folding display unit which is foldable with reference to a folding axis extending in a first direction and a first non-folding display unit and a second non-folding display unit which are spaced apart from each other with the folding display unit therebetween: a support member disposed below the display module, and including a folding part having a plurality of patterns defined therein and corresponding to the folding display unit and a first non-folding part and a second non-folding part respectively corresponding to the first non-folding display unit and the second non-folding display unit; and an adhesive layer disposed between the display module and the support member, wherein the adhesive layer has a modulus of about 1 megapascal (MPa) to about 1500 MPa at −20 degrees Celsius (° C.).

In an embodiment, the adhesive layer may be directly disposed on the support member.

In an embodiment, the folding part may have a modulus of about 100 MPa to about 600 MPa at −20° C.

In an embodiment, the support member may have a thickness of about 100 micrometers (μm) to about 400 μm.

In an embodiment, the adhesive layer may have a thickness of about 10 μm to about 30 μm.

In an embodiment, the support member may include a first surface adjacent to the display module and a second surface facing the first surface, and the plurality of patterns may include a first groove recessed in a direction from the first surface to the second surface and a second groove recessed in the direction from the second surface to the first surface.

In an embodiment, the first groove may not overlap the second groove.

In an embodiment, the first groove and the second groove may be alternately arranged in a second direction perpendicular to the first direction.

In an embodiment, the electronic device may further include a first resin portion filled in the first groove, and a second resin portion filled in the second groove.

In an embodiment, the first resin portion and the second resin portion may each include an acrylic resin.

In an embodiment, the plurality of patterns may include a plurality of openings arranged in a second direction perpendicular to the first direction.

In an embodiment, the plurality of openings may include first sub-openings arranged in the first direction and second sub-openings spaced apart from the first sub-openings in the second direction perpendicular to the first direction and arranged in the first direction.

In an embodiment, the support member may be a glass substrate.

In an embodiment, the electronic device may further include a hard coating layer disposed between the support member and the adhesive layer.

In an embodiment, the hard coating layer may have a thickness of about 1 μm to about 5 μm.

In an embodiment, the hard coating layer may have a modulus of about 1000 MPa to about 1500 MPa.

In an embodiment, the hard coating layer may be directly disposed on the support member, and the adhesive layer may be directly disposed on the hard coating layer.

In an embodiment, the support member may have a thickness of about 100 μm to about 400 μm, and the folding part may have a modulus of about 100 MPa to about 600 MPa at −20° C.

In an embodiment, the adhesive layer may have a thickness of about 10 μm to about 30 μm, and the support member may have a thickness of about 100 μm to about 400 μm.

In an embodiment, the support member may have a thickness of about 100 μm to about 400 μm, the folding part may have a modulus of about 100 MPa to about 600 MPa at −20° C., and the adhesive layer may have a thickness of about 10 μm to about 30 μm.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view illustrating an embodiment of an electronic device in an unfolded state;

FIG. 1B is a perspective view illustrating that the electronic device illustrated in FIG. 1A is being in-folded;

FIG. 1C is a perspective view illustrating that the electronic device illustrated in FIG. 1A is being out-folded;

FIG. 2A is a perspective view illustrating an embodiment of an electronic device in an unfolded state;

FIG. 2B is a perspective view illustrating that the electronic device illustrated in FIG. 2A is being in-folded;

FIG. 2C is a perspective view illustrating that the electronic device illustrated in FIG. 2A is being out-folded;

FIG. 3A is an exploded perspective view of an embodiment of an electronic device;

FIG. 3B is a cross-sectional view of an embodiment of a display panel;

FIG. 4A is a cross-sectional view of an embodiment of an electronic device;

FIG. 4B is a cross-sectional view of an embodiment of an electronic device;

FIG. 5A is a plan view of an embodiment of a support member;

FIG. 5B is a perspective view of an embodiment of a support member;

FIG. 6 is a plan view of an embodiment of a support member;

FIG. 7A is a cross-sectional view of an embodiment of an electronic device:

FIG. 7B is a cross-sectional view of an embodiment of an electronic device:

FIG. 8A schematically illustrates a folded electronic device; and

FIG. 8B schematically illustrates a folded electronic device.

### DETAILED DESCRIPTION

The inventive concept may be implemented in various modifications and have various forms, and illustrative embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the inventive concept.

In this specification, it will be understood that when an element (or region, layer, portion, or the like) is also referred to as being “on”, “connected to” or “coupled to” another element, it may be directly disposed/connected/coupled to another element, or intervening elements may be disposed therebetween.

In this specification, it will be understood that “being directly disposed” means that there are no intervening layers, films, regions, plates, or the like between a portion of layers, films, regions, plates, or the like and another portion. In an embodiment, “being directly disposed” may mean to be disposed between two layers or two members without using an additional member such as an adhesive member or like.

Like reference numerals or symbols refer to like elements throughout. In the drawings, the thickness, the ratio, and the dimension of the elements are exaggerated for effective description of the technical contents. The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

The terms such as “below”, “lower”, “above”, “upper” and the like, may be used herein for the description to describe one element's relationship to another element illustrated in the drawing figures. It will be understood that the terms have a relative concept and are described on the basis of the orientation depicted in the drawing figures. In this specification, “being disposed on” may mean to be disposed not only on an upper part but also on a lower part of one member.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Hereinafter, a window and an electronic device in an embodiment of the inventive concept will be described with reference to the accompanying drawings.

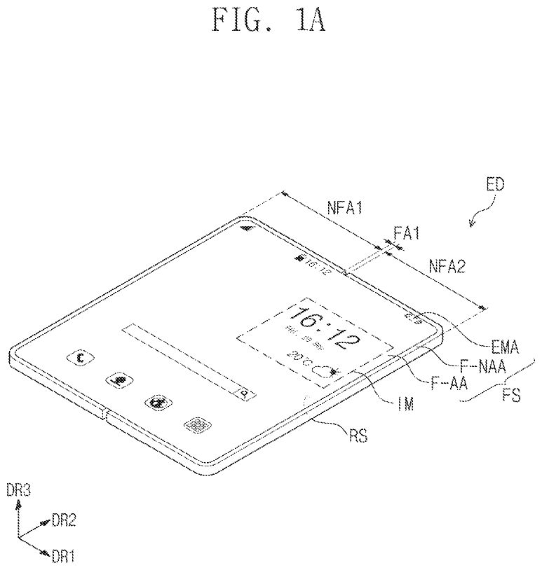

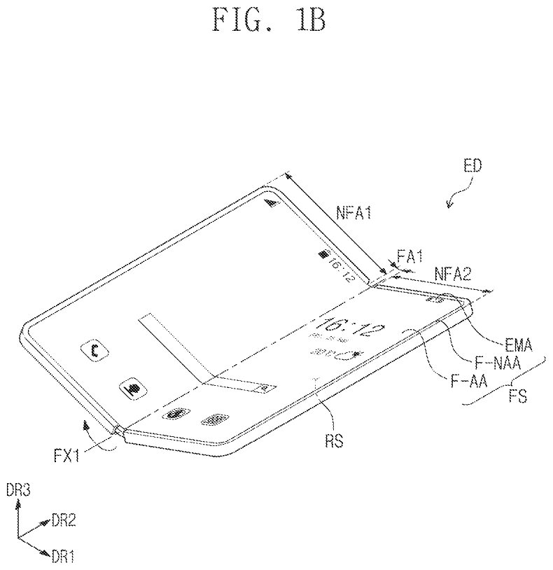

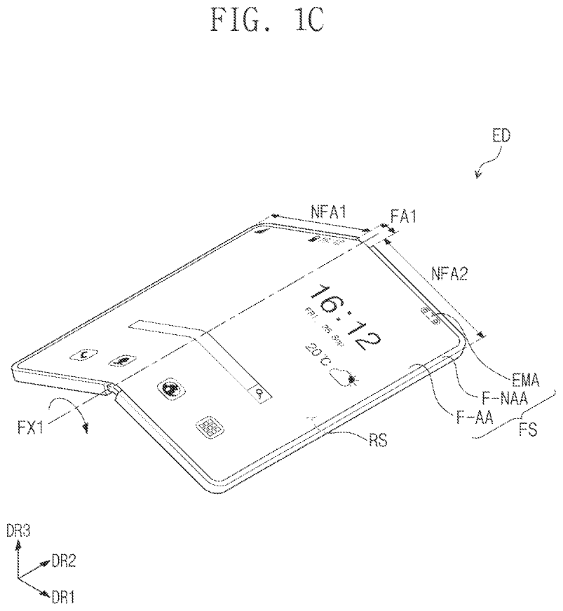

FIG. 1A is a perspective view illustrating an embodiment of an electronic device in an unfolded state. FIG. 1B is a perspective view illustrating that the electronic device illustrated in FIG. 1A is being in-folded. FIG. 1C is a perspective view illustrating that the electronic device illustrated in FIG. 1A is being out-folded.

An electronic device ED in an embodiment may be a device activated in response to an electrical signal. In an embodiment, the electronic device ED may be a mobile phone, a tablet computer, a car navigation system, a game console, or a wearable device, for example, but the inventive concept is not limited thereto. In FIG. 1A, etc., of the specification, the electronic device ED is illustrated as a mobile phone.

Referring to FIGS. 1A to 1C, the electronic device ED in an embodiment may include a first display surface FS defined by a first direction axis DR1 and a second direction axis DR2 crossing the first direction axis DR1. The electronic device ED may provide an image IM to users through the first display surface FS. The electronic device ED in an embodiment may display, in a third direction axis DR3, the image IM on the first display surface FS parallel to each of the first direction axis DR1 and the second direction axis DR2. In this specification, a front surface (or upper surface) and a rear surface (or lower surface) of each member are defined based on a direction in which the image IM is displayed. The front surface and the rear surface may be opposed to each other in the third direction axis DR3, and the normal direction of each of the front surface and the rear surface may be parallel to the third direction axis DR3.

The electronic device ED in an embodiment may include a first display surface FS and a second display surface RS. The first display surface FS may include an active region F-AA and a peripheral region F-NAA. The active region F-AA may include an electronic module region EMA. The second display surface RS may be defined as a surface opposed to at least a portion of the first display surface FS. That is, the second display surface RS may be defined as a portion of the rear surface of the electronic device ED.

The electronic device ED in an embodiment may detect an external input applied from the outside. The external input may include various types of inputs applied from the outside of the electronic device ED. In an embodiment, the external input may include not only touch by a part of the user's body such as user's hand but also an external input (e.g., hovering) applied while approaching or being adjacent within a predetermined distance to the electronic device ED, for example. In addition, the external input may have various forms such as force, pressure, temperature, light, or the like.

In FIG. 1A and the following drawings, the first direction axis DR1 to the third direction axis DR3 are illustrated, and the directions indicated by the first to third direction axes DR1, DR2, and DR3 illustrated in this specification may have a relative concept and thus may be changed to other directions. In addition, the directions indicated by the first to third direction axes DR1, DR2, and DR3 may be also referred to as first to third directions, and may thus be denoted as the same reference numerals or symbols.

The active region F-AA of the electronic device ED may be a region activated in response to an electrical signal. The electronic device ED in an embodiment may display the image IM through the active region F-AA. Also, various types of external inputs may be detected in the active region F-AA. The peripheral region F-NAA may be adjacent to the active region F-AA. The peripheral region F-NAA may have a predetermined color. The peripheral region F-NAA may surround the active region F-AA. Accordingly, a shape of the active region F-AA may be substantially defined by the peripheral region F-NAA. However, this is merely one of embodiments, and the peripheral region F-NAA may be disposed adjacent to only one side of the active region F-AA or may be omitted. The electronic device ED in an embodiment of the inventive concept may include active regions having various shapes, but is not limited to any particular embodiment.

The electronic device ED may include a folding region FA1 and non-folding regions NFA1 and NFA2. In an embodiment, the non-folding regions NFA1 and NFA2 may be disposed adjacent to the folding region FA1 while sandwiching the folding region FA1. The electronic device ED in an embodiment may include the first non-folding region NFA1 and the second non-folding region NF A2 which are spaced apart from each other in the first direction axis DR1 with the folding region FA1 therebetween. In an embodiment, the first non-folding region NFA1 may be disposed on one side of the folding region FA1 in the first direction axis (also referred to as a first direction) DR1, and the second non-folding region NF A2 may be disposed on the other side of the folding region FA1 in the first direction DR1, for example.

FIGS. 1A to 1C illustrate an embodiment of the electronic device ED including one folding region FA1, but the inventive concept is not limited thereto. A plurality of folding regions may be defined in the electronic device ED. In an embodiment, an electronic device in an embodiment may include two or more folding regions and also include three or more non-folding regions disposed with respective folding regions therebetween, for example.

Referring to FIG. 1B, the electronic device ED in an embodiment may be folded with respect to a first folding axis FX1. The first folding axis FX1 may be an imaginary axis extending in the second direction axis DR2 and be parallel to a long side direction of the electronic device ED. On the first display surface FS, the first folding axis FX1 may extend in the second direction axis DR2.

The electronic device ED may be folded with respect to the first folding axis FX1 and be changed into an in-folded state where in the first display surface FS, one region overlapping the first non-folding region NFA1 and the other region overlapping the second non-folding region NFA2 face each other.

In an in-folded state, the second display surface RS of the electronic device ED in an embodiment may be visible to a user. The second display surface RS may further include an electronic module region in which an electronic module including various components is disposed, but is not limited to any particular embodiment.

Referring to FIG. 1C, the electronic device ED in an embodiment may be folded with respect to the first folding axis FX1 and be changed into an out-folded state where in the second display surface RS, one region overlapping the first non-folding region NFA1 and the other region overlapping the second non-folding region NFA2 face each other.

However, the inventive concept is not limited thereto and the electronic device ED may be folded with respect to a plurality of folding axes, so that respective portions of the first display surface FS and the second display surface RS face each other. The number of folding axes and the number of non-folding regions corresponding thereto are not particularly limited.

Various electronic modules may be disposed in the electronic module region EMA. In an embodiment, the electronic module may include at least one of a camera, a speaker, a light detection sensor, or a heat detection sensor, for example. The electronic module region EMA may detect an external subject received through the first display surface FS or the second display surface RS or provide a sound signal such as voice to the outside through the first display surface FS or the second display surface RS. The electronic module may include a plurality of components, and is not limited to any particular embodiment.

The electronic module region EMA may be surrounded by the active region F-AA and the peripheral region F-NAA, but is not limited thereto. The electronic module region EMA may be disposed in the active region F-AA, and is not limited to any particular embodiment.

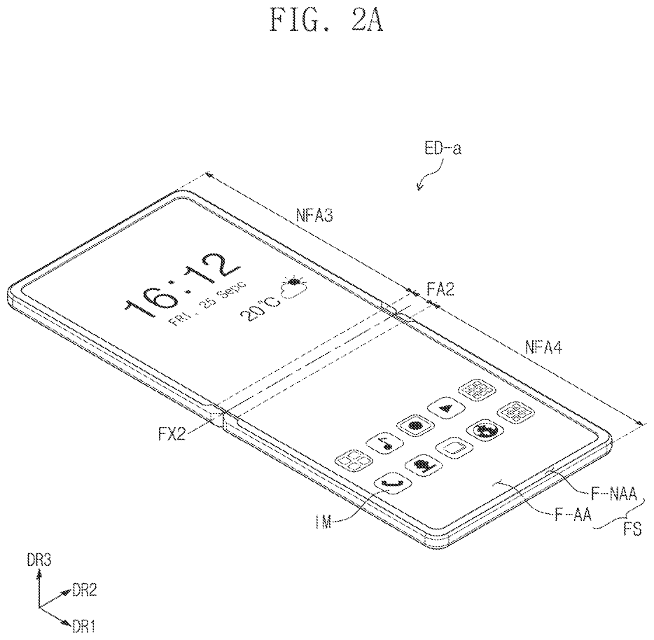

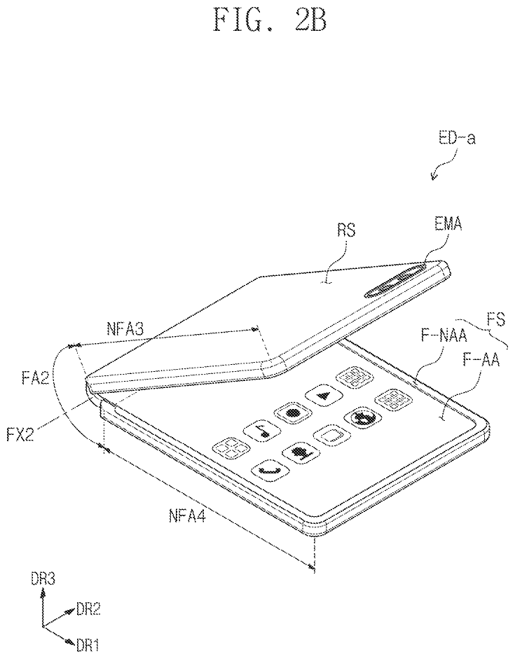

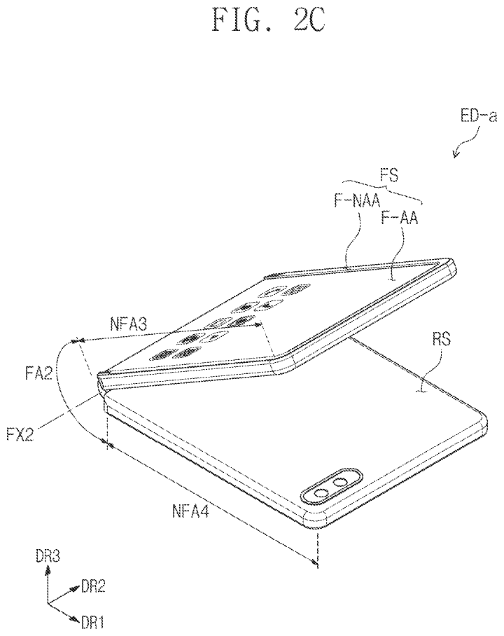

FIG. 2A is a perspective view illustrating an embodiment of an electronic device in an unfolded state. FIG. 2B is a perspective view illustrating that the electronic device illustrated in FIG. 2A is being in-folded. FIG. 2C is a perspective view illustrating that the electronic device illustrated in FIG. 2A is being out-folded.

An electronic device ED-a in an embodiment may be folded with respect to a second folding axis FX2 extending in one direction parallel to the second direction axis DR2. FIG. 2B illustrates that an extending direction of the second folding axis FX2 is parallel to an extending direction of a short side of the electronic device ED-a. However, the inventive concept is not limited thereto.

The electronic device ED-a in an embodiment may include at least one folding region FA2 and non-folding regions NFA3 and NFA4 adjacent to the folding region FA2. The non-folding regions NFA3 and NFA4 may be spaced apart from each other with the folding region FA2 therebetween.

The folding region FA2 may have a predetermined curvature and curvature radius. In an embodiment, the electronic device ED-a may be in-folded such that the first non-folding region NFA3 and the second non-folding region NFA4 may face each other, and the display surface FS is not exposed to the outside. In addition, referring to FIG. 2C, the electronic device ED-a in an embodiment may be out-folded such that the first display surface FS is exposed to the outside.

The electronic device ED-a in an embodiment may include a second display surface RS, which may be defined as a surface opposing at least a portion of the first display surface FS. The second display surface RS may include an electronic module region EMA in which an electronic module including various components is disposed. In addition, an image or a video may be displayed on at least a portion of the second display surface RS.

In an embodiment, the first display surface FS of the electronic device ED-a may be visible to a user in an unfolded state, and the second display surface RS of the electronic device ED-a may be visible to a user in an in-folded state.

In an embodiment, the electronic devices ED and ED-a may repeatedly perform an in-folding or out-folding operation from an unfolding operation and vice versa, but the inventive concept is not limited thereto. In an embodiment, the electronic devices ED and ED-a may select at least one of an unfolding operation, in-folding operation, or out-folding operation. Also, when a plurality of folding regions are included, at least one folding direction in the plurality of folding regions may be different from a folding direction in the other folding regions. In an embodiment, when two folding regions are included, two non-folding regions with one folding region therebetween may be in-folded, and two non-folding regions with the other folding region therebetween may be out-folded, for example.

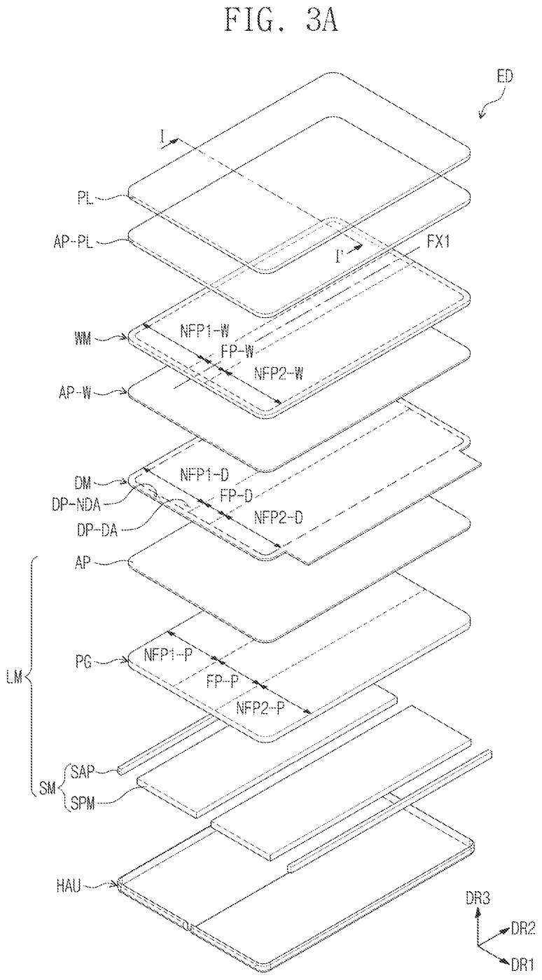

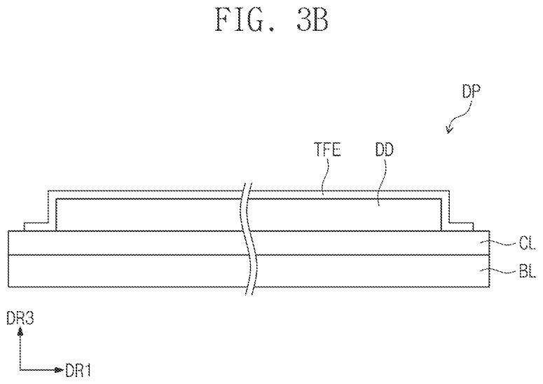

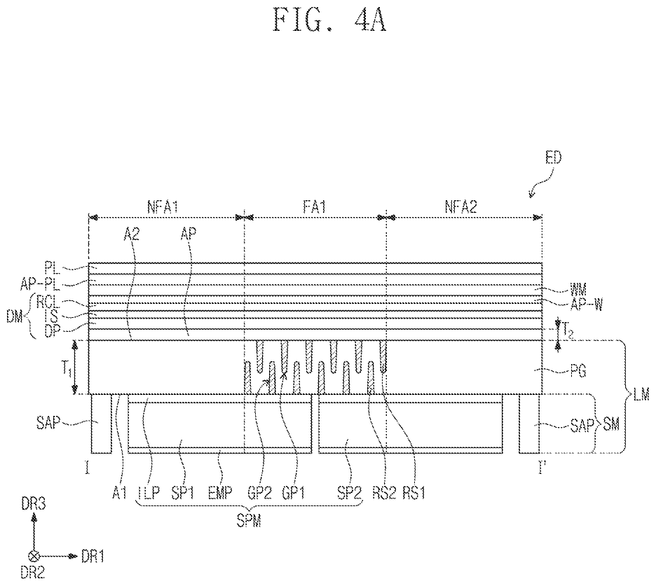

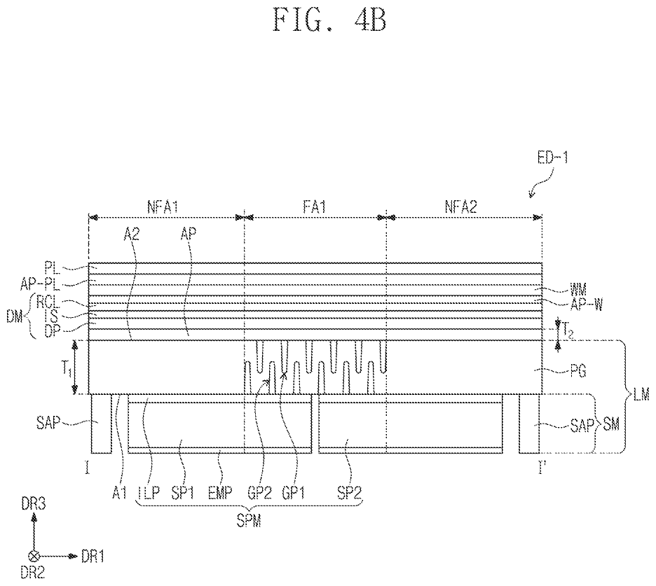

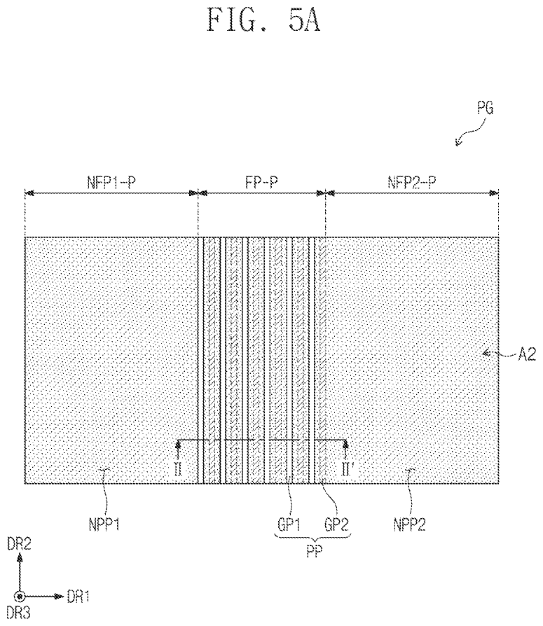

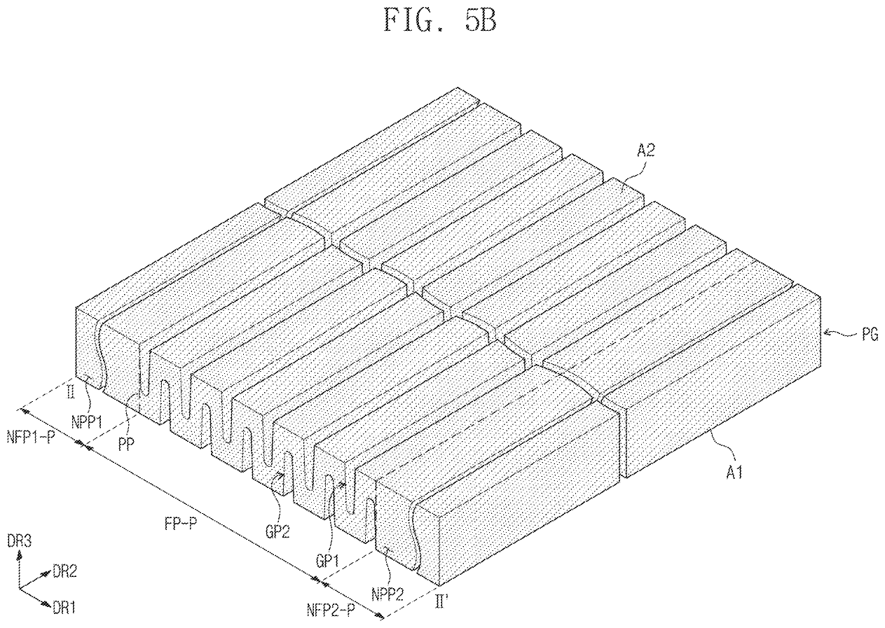

FIG. 3A is an exploded perspective view of an embodiment of an electronic device. FIG. 3B is a cross-sectional view of a display panel. FIG. 4A is a cross-sectional view of an embodiment of an electronic device. FIG. 4B is a cross-sectional view of an embodiment of an electronic device. FIG. 5A is a plan view of an embodiment of a support member. FIG. 5B is a perspective view of an embodiment of a support member taken along line II-II′ of FIG. 5A. FIG. 3A illustrates an exploded perspective view of an embodiment of the electronic device illustrated in FIG. 1A. FIG. 4A is a cross-sectional view illustrating a portion taken along line I-I′ of FIG. 3. FIG. 4B is a cross-sectional view illustrating a portion taken along line I-I′ of FIG. 3.

FIGS. 3A to 5B, etc., illustrate that the folding axis FX1 of the electronic device ED illustrated in FIG. 1A, etc., is parallel to a long side of the electronic device ED, and the inventive concept is not limited thereto. As illustrated in FIG. 2A, etc., the contents to be described with reference to the following drawings may also be applied to the case where the second folding axis FX2 is parallel to a short side of the electronic device.

Referring to FIGS. 3A to 4B, the electronic device ED in an embodiment may include a display module DM, a lower module LM disposed below the display module DM, and an adhesive layer AP disposed between the display module DM and the lower module LM. Also, the electronic device ED in an embodiment may further include a window WM disposed above the display module DM.

The electronic device ED in an embodiment may further include a window adhesive layer AP-W disposed between the display module DM and the window WM and also may further include a protective film PL and a protective adhesive layer AP-PL which are disposed above the window WM. In the electronic device ED in an embodiment, the protective film PL and the protective adhesive layer AP-PL may be omitted. When the protective film PL and the protective adhesive layer AP-PL are omitted, the window WM may serve as the uppermost surface of the electronic device ED.

The electronic device ED may include a housing HAU that accommodates the display module DM and the lower module LM. The housing HAU may be coupled to the window WM. Although not illustrated, the housing HAU may further include a hinge structure for facilitating a folding or bending operation. The window WM may be a cover window disposed on the display module DM.

The electronic device ED in an embodiment may include a window adhesive layer AP-W disposed between the display module DM and the window WM. The window adhesive layer AP-W may be an optically clear adhesive film (“OCA”) or an optically clear adhesive resin layer (“OCR”). In an embodiment, the window adhesive layer AP-W may be omitted.

The window WM may cover an entirety of the upper surface of the display module DM. The window WM may have a shape corresponding to a shape of the display module DM. The window WM may include glass and be used as a cover window for the electronic device.

The window WM may include a folding part FP-W and non-folding parts NFP1-W and NFP2-W. A first non-folding part NFP1-W and a second non-folding part NFP2-W of the window WM may be spaced apart from each other with the folding part FP-W therebetween in the first direction DR1. The folding part FP-W may correspond to the folding region FAI (refer to FIG. 1A), and the non-folding parts NFP1-W and NFP2-W may correspond to the non-folding regions NFA1 and NFA2 (refer to FIG. 1A).

In an embodiment, the window WM may have a bonded glass structure in which a plurality of glass substrates are bonded. The bonded glass substrates may each be a tempered glass substrate. In addition, the bonded glass substrates may each be an ultra-thin glass substrate. The window WM in an embodiment will be described later in more detail.

The display module DM may display an image in response to an electrical signal and transmit/receive information about an external input. The display module DM may include a display region DP-DA and a non-display region DP-NDA. The display region DP-DA may be defined as a region where an image provided from the display module DM is displayed.

The non-display region DP-NDA is adjacent to the display region DP-DA. In an embodiment, the non-display region DP-NDA may surround the display region DP-DA, for example. However, this is merely one of embodiments, and the non-display region DP-NDA may be defined as various shapes and is not limited to any particular embodiment. In an embodiment, the display region DP-DA of the display module DM may correspond to at least a portion of the active region F-AA (refer to FIG. 1A).

In an embodiment, the display module DM may include a display panel DP. The display panel DP may be a light-emitting display panel, and is not particularly limited thereto. In an embodiment, the display panel DP may be an organic light-emitting display panel or an inorganic light-emitting display panel, for example. A light-emitting layer of the organic light-emitting display panel may include an organic light-emitting material. A light-emitting layer of the inorganic light-emitting display panel may include quantum dots, quantum rods, or the like.

Referring to FIG. 3B, the display panel DP in an embodiment may include a base layer BL, a circuit layer CL provided on the base layer BL, a light-emitting element layer DD dispose on the circuit layer CL, and an encapsulation layer TFE disposed on the light-emitting element layer DD. In the display panel DP in an embodiment, the base layer BL may be a member that provides a base surface on which the light-emitting element layer DD is disposed. The base layer BL may be a glass substrate, a metal substrate, a plastic substrate, or the like. However, the inventive concept is not limited thereto, and the base layer BL may be an inorganic layer, an organic layer, or a composite material layer.

In an embodiment, the circuit layer CL may be disposed on the base layer BL, and the circuit layer CL may include a plurality of transistors (not illustrated). The transistors (not illustrated) may respectively include a control electrode, an input electrode, and an output electrode. In an embodiment, the circuit layer CL may include a switching transistor and a driving transistor for driving a light-emitting element, for example.

The display panel DP in an embodiment may include the light-emitting element layer DD and the encapsulation layer TFE disposed on the light-emitting element layer DD. The encapsulation layer TFE may cover the light-emitting element layer DD. The encapsulation layer TFE may be disposed to cover the light-emitting element layer DD and seal the light-emitting element layer DD. The encapsulation layer TFE may include at least one organic film and at least one inorganic film.

The display module DM may further include an input sensor IS. The input sensor IS may be directly disposed on the display panel DP. The input sensor IS may include a plurality of sensing electrodes. The input sensor IS may detect an external input in a self-capacitance manner or a mutual capacitance manner. The input sensor IS may detect an input from an active-type input device.

When the display panel DP is manufactured, the input sensor IS may be directly formed on the display panel DP through a continuous process. However, the inventive concept is not limited thereto, and the input sensor IS may be manufactured as a panel separately from the display panel DP and attached to the display panel DP by the adhesive layer (not illustrated).

Also, the display module DM may further include an optical layer RCL. The optical layer RCL may function to reduce reflection of external light. In an embodiment, the optical layer RCL may include a polarization layer or a color filter layer, for example. However, the inventive concept is not limited thereto, and the optical layer RCL may include optical members for improving display quality of the electronic device ED.

In an embodiment, the optical layer RCL may be directly disposed on the input sensor IS. In addition, when the input sensor IS is omitted in the display module DM, the optical layer RCL may be directly disposed on the display panel DP. However, the inventive concept is not limited thereto, and the optical layer RCL may be disposed on the display panel DP or the input sensor IS by an additional adhesive member.

The display module DM may include a folding display unit FP-D and non-folding display units NFP1-D and NFP2-D. The folding display unit FP-D may be a portion corresponding to the folding region FA1 (refer to FIG. 1A), and the non-folding display units NFP1-D and NFP2-D may be portions corresponding to the non-folding regions NFA1 and NFA2, (refer to FIG. 1A).

The folding display unit FP-D may be a portion which is folded or bent with respect to the first folding axis FX1 (refer to FIGS. 1B and 1C). The display module DM may include the first non-folding display unit NFP1-D and the second non-folding display unit NFP2-D, and the first non-folding display unit NFP1-D and the second non-folding display unit NFP2-D are spaced apart from each other with the folding display unit FP-D therebetween.

In the electronic device ED in an embodiment, the lower module LM may include a support member PG. The lower module LM may further include a support module SM disposed below the support member PG. The support member PG may be directly disposed on the support module SM. However, this is merely one of embodiments, and the inventive concept is not limited thereto. In an embodiment, another component may be disposed between the support member PG and the support module SM, for example.

In an embodiment, the support member PG may be disposed below the display module DM. The support member PG may be a glass substrate. However, this is merely one of embodiments, and the inventive concept is not limited thereto. In an embodiment, the support member PG may be a plastic substrate or a metal substrate, for example.

The support member PG may include a folding part FP-P and first and second non-folding parts NFP1-P and NFP2-P. The first non-folding part NFP1-P and the second non-folding part NFP2-P may be spaced apart from each other with the folding part FP-P therebetween. The folding part FP-P may be a portion corresponding to the folding region FA1 (refer to FIG. 1A), and the non-folding parts NFP1-P and NFP2-P may be portions corresponding to the non-folding regions NFA1 and NFA2 (refer to FIG. 1A).

Referring to FIG. 4A, FIG. 5A, and FIG. 5B, the folding part FP-P may include a plurality of patterns PP. The folding part FP-P in an embodiment may include a plurality of patterns and thus have a relatively lower modulus value. In an embodiment, the first and second non-folding parts NFP1-P and NFP2-P may respectively include first and second patterns NPP1 and NPP2.

The support member PG may include a first surface A1 and a second surface A2 facing the first surface A1, the first surface A1 and the second surface A2 adjacent to the display module DM, and the patterns PP may include first grooves GP1 recessed in the direction from the first surface A1 to the second surface A2 and second grooves GP2 recessed in the direction from the second surface A2 to the first surface A1.

The first grooves GP1 may be arranged in the first direction DR1. The second grooves GP2 may be arranged in the first direction DR1. The first grooves GP1 and the second grooves GP2 may be alternately arranged in the first direction DR1. The first grooves GPI may not overlap the second grooves GP2.

The shapes, numbers, and arrangements of the first grooves GP1 and the second grooves GP2, which are illustrated in FIG. 4A, FIG. 5A, and FIG. 5B, are merely illustrative embodiments, and the inventive concept is not limited thereto. In an embodiment, FIG. 4A, FIG. 5A, and FIG. 5B illustrate that the first grooves GP1 and the second grooves GP2 each include a curved surface, but the first grooves GP1 and the second grooves GP2 may not be included, for example. FIG. 4A, FIG. 5A, and FIG. 5B illustrate that the number of the first grooves GPI is the same as the number of the second grooves GP2, but the number of the first grooves GP1 may be different from the number of the second grooves GP2.

In an embodiment, a first resin portion RS1 may be filled in the first grooves GP1. Also, a second resin portion RS2 may be filled in the second grooves GP2. The first resin portion RSI and the second resin portion RS2 may each include an acrylic resin. The first resin portion RSI and the second resin portion RS2 may respectively planarize the first surface A1 and the second surface A2 of the support member PG. However, this is merely one of embodiments, and the inventive concept is not limited thereto. In an embodiment, as illustrated in FIG. 4B, the inside of the first groove GP1 and the inside of the second groove GP2 may each be an empty space, for example.

The folding part FP-P may have a modulus of about 100 megapascal (MPa) to about 600 MPa at −20 degrees Celsius (° C.). The folding part FP-P may have a modulus of about 1.0 MPa to about 1500 MPa at −20° C. to protect the display module DM against an external impact and also have flexibility. Therefore, the electronic device ED including the support member PG including the folding part FP-P may have substantially excellent impact resistance and also have flexibility.

When the folding part FP-P has a modulus of less than about 100 MPa at −20° C., the folding part FP-P has relatively low impact resistance and thus there is a limitation in protecting the display module DM against an external impact. In this case, an external impact may cause the encapsulation layer TFE included in the display module DM to be fractured. When the folding part FP-P has a modulus of greater than about 600 MPa at −20° C., the flexibility becomes poor and thus there may be a limitation in a folding operation of the electronic device ED including the support member PG.

The support member PG may have a thickness T₁ of about 100 micrometers (μm) to about 400 μm. In an embodiment, the thickness may refer to a length in the third direction axis DR3. When the support member PG has a thickness T₁ of less than about 100 μm, the folding part FP-P has relatively low impact resistance and thus there is a limitation in protecting the display module DM against an external impact. In this case, an external impact may cause the encapsulation layer TFE included in the display module DM to be fractured. When the support member PG has a thickness T₁ of greater than about 400 μm, the flexibility becomes poor and thus there may be a limitation in a folding operation of the electronic device ED including the support member PG.

An adhesive layer AP may be disposed between the display module DM and the support member PG. The adhesive layer AP may be directly disposed on the support member PG. The display module DM may be directly disposed on the adhesive layer AP. However, this is merely one of embodiments, and the inventive concept is not limited thereto. In an embodiment, other components may be disposed between the adhesive layer AP and the display module DM or between the adhesive layer AP and the support member PG, for example.

The adhesive layer AP may be an optically clear adhesive film (“OCA”) or an optically clear adhesive resin layer (“OCR”). However, the inventive concept is not limited thereto, and the adhesive layer AP may be an adhesive layer having a relatively low transmittance of about 80% or less.

The adhesive layer AP may have a modulus of about 1.0 MPa to about 1500 MPa at −20° C. The adhesive layer AP may have a modulus of about 1.0 MPa to about 1500 MPa at −20° C. to protect the display module DM against an external impact and also have flexibility. Therefore, the electronic device ED including the adhesive layer AP may have substantially excellent impact resistance and also have flexibility.

When the adhesive layer AP has a modulus of less than about 1.0 MPa at −20° C., the adhesive layer AP has a relatively low impact resistance and thus the display module DM may not be protected against an external impact. In this case, an external impact may cause the encapsulation layer TFE included in the display module DM to be fractured. When the adhesive layer AP has a modulus of greater than about 1500 MPa at −20° C., the flexibility becomes poor and thus there may be a limitation in a folding operation of the electronic device ED including the adhesive layer AP.

The adhesive layer AP may have a thickness T₂ of about 10 μm to about 30 μm. When the adhesive layer AP has a thickness T₂ of less than about 10 μm, the adhesive layer AP has a relatively low impact resistance and thus there is a limitation in protecting the display module DM against an external impact. In this case, an external impact may cause the encapsulation layer TFE, etc., included in the adhesive layer AP to be fractured. When the adhesive layer AP has a thickness T₂ of greater than about 30 μm, the flexibility becomes poor and thus there is a limitation in a folding operation of the electronic device ED including the adhesive layer AP.

In an embodiment, the folding part FP-P may have a modulus of about 100 MPa to about 600 MPa at −20° C., and the adhesive layer AP may have a modulus of about 1 MPa to about 1500 MPa at −20° C. In an embodiment, the folding part FP-P may have a thickness T₁ of about 100 μm to about 400 μm, and the adhesive layer AP may have a thickness T₂ of about 10 μm to about 30 μm.

In an embodiment, the folding part FP-P may have a modulus of about 100 MPa to about 600 MPa at −20° C., and the adhesive layer AP may have a modulus of about 1 MPa to about 1500 MPa at −20° C. In an embodiment, the folding part FP-P may have a thickness T₁ of about 100 μm to about 400 μm, and the adhesive layer AP may have a thickness T₂ of about 10 μm to about 30 μm. In an embodiment, the folding part FP-P may have a modulus of about 100 MPa to about 600 MPa at −20° C., the adhesive layer AP may have a modulus of about 1 MPa to about 1500 MPa at −20° C., the folding part FP-P may have a thickness T₁ of about 100 μm to about 400 μm, and the adhesive layer AP may have a thickness T₂ of about 10 μm to about 30 μm.

The electronic device ED in an embodiment may include a support module SM. The support module SM may include a support part SPM and a filling part SAP. The support part SPM may overlap most of regions of the display module DM. The filling part SAP may be disposed outside the support part SPM and overlap an outer periphery of the display module DM.

The support module SM may include support layers SP1 and SP2. The support layers SP1 and SP2 may include a first sub-support layer SP1 and a second sub-support layer SP2 spaced apart from each other in the direction of the first direction axis DR1. The first sub-support layer SP1 and the second sub-support layer SP2 may be spaced apart from each other at a portion corresponding to the first folding axis FX1 (refer to FIGS. 1B and 1C). The support layers SP1 and SP2 are spaced apart from each other in the folding region FA1 and are provided as the first sub-support layer SP1 and the second sub-support layer SP2 and thus the folding or bending characteristics of the electronic device ED may be improved. Although not illustrated, the support layers SP1 and SP2 may include components of a cushion layer (not illustrated) and a lower support plate (not illustrated) which are stacked in the thickness direction.

The lower support plate (not illustrated) may include a metal material or a polymer material. In an embodiment, the lower support plate may include or consist of a stainless steel, an aluminum, a copper, or any alloys thereof, for example.

The cushion layer (not illustrated) may prevent the support member PG from being pressed or deformed by an external impact and force. The cushion layer (not illustrated) may include an elastomer, etc., such as a sponge, a foam, or a urethane resin. In addition, the cushion layer (not illustrated) may include or consist of at least one of an acrylic polymer, a urethane-based polymer, a silicone-based polymer, or an imide-based polymer. However, the inventive concept is not limited thereto. The cushion layer (not illustrated) may be disposed below the support member PG or below the lower support plate (not illustrated).

Also, the support module SM may further include at least one of a shielding layer EMP and an interlayer-bonding layer ILP. The shielding layer EMP may be an electromagnetic wave shielding layer or a heat dissipation layer. In addition, the shielding layer EMP may function as a bonding layer. The shielding layer EMP may bond the support module SM and the housing HAU.

The support module SM may further include an interlayer-bonding layer ILP disposed above the support layers SP1 and SP2. The interlayer-bonding layer ILP may bond the support member PG and the support module SM. The interlayer-bonding layer ILP may be provided in a form of a bonding resin layer or an adhesive tape. In an embodiment, the interlayer-bonding layer ILP may be obtained by removing a portion overlapping the folding display unit FP-D, for example. However, the inventive concept is not limited thereto, and the interlayer-bonding layer ILP may overlap the entirety of the folding display unit FP-D.

The filling part SAP may be disposed in outer peripheries of the support layers SP1 and SP2. The filling part SAP may be disposed between the support plate and the housing HAU. The filling part SAP may fill the space between the support member PG and the housing HAU and fix the support member PG.

In the electronic device ED in an embodiment, a combination of components included in the lower module LM may vary according to the size and shape of the electronic device ED, or the operating properties of the electronic device ED, or the like.

The electronic device ED in an embodiment may further include a protective film PL disposed above the window WM. The protective film PL may be disposed above the window WM to protect the window WM from an external environment. However, in the electronic device ED in an embodiment, the protective film PL may be omitted and thus the window WM may serve as the uppermost surface of the electronic device ED.

A protective adhesive layer AP-PL may be further disposed between the window WM and the protective film PL. The protective adhesive layer AP-PL may be an optically clear adhesive layer. When the electronic device ED in an embodiment includes the protective film PL, the protective film PL may be a layer exposed to the outside from the electronic device ED.

The protective film PL may have optical properties having a transmittance of about 90% or more in a visible light range and a haze value of less than about 1%. The protective film PL may include a polymer film. In addition, the protective film PL may have a base layer of a polymer film and further include, above the base layer, a functional layer, such as a hard coating layer, an anti-fingerprint coating layer, and an anti-static coating layer. The protective film PL used for the electronic device ED in an embodiment may have flexibility.

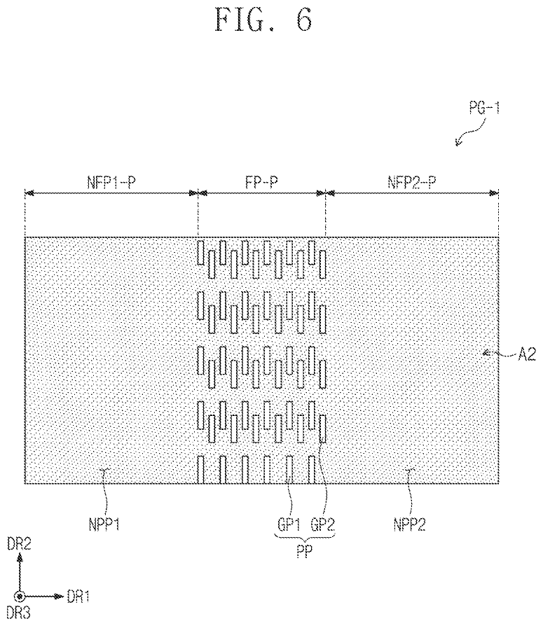

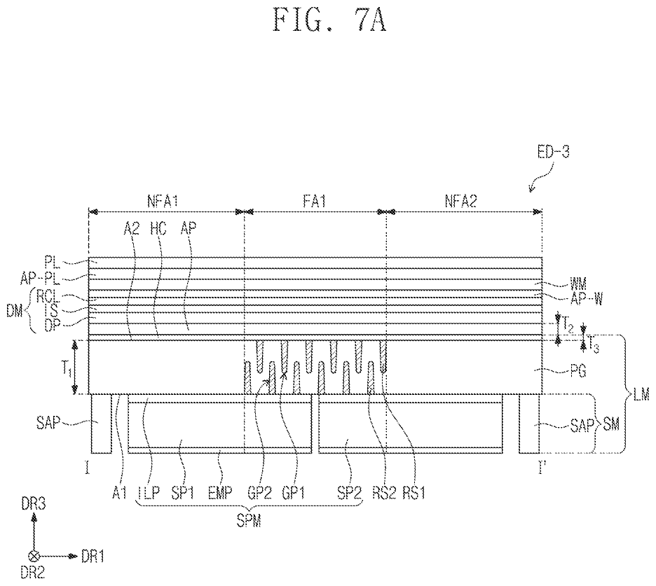

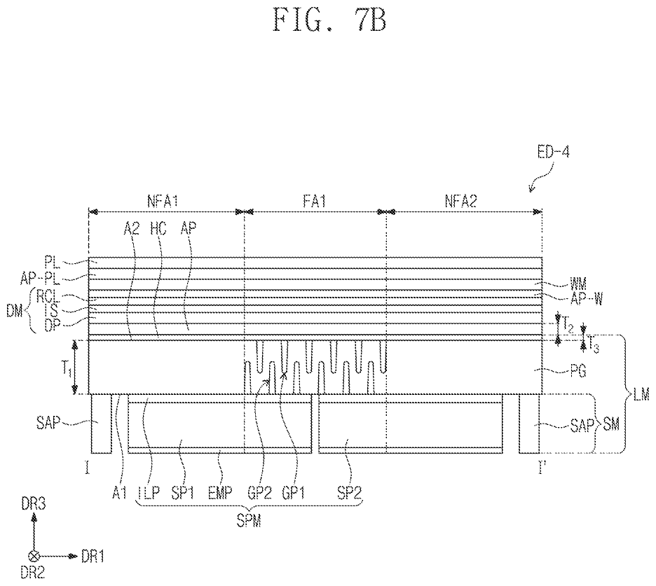

FIG. 6 is a plan view of an embodiment of a support member. FIG. 7A is a cross-sectional view of an electronic device. FIG. 7B is a cross-sectional view of an embodiment of an electronic device. FIG. 7A is a cross-sectional view taken along line I-I′ of FIG. 3A. FIG. 7B is a cross-sectional view taken along line I-I′ of FIG. 3A. The contents duplicated with those made with the references to FIGS. 1A to 5B will not be explained again, and the following description will be mainly focused on the differences.

Referring to FIG. 6, patterns PP of a support member PG-1 in an embodiment may include a plurality of openings GP1 and GP2 arranged in the first direction DR1. The openings GP1 and GP2 may include first sub-openings GP1 arranged in the second direction axis (also referred to as a second direction) DR2 and second sub-openings GP2 which are spaced apart from the first sub-openings GP1 in the first direction DR1 and are arranged in the second direction DR2. The first sub-openings GP1 and the second sub-openings GP2 may be alternately arranged in the first direction DR1. The support member PG in an embodiment may have the plurality of openings GP1 and GP2 defined in the folding part FP-P. Accordingly, the folding part FP-P may have a modulus of about 100 MPa to about 600 MPa at −20° C.

Referring to FIG. 7A and FIG. 7B, the lower module LM of the electronic device ED-3 and ED-4 may further include a hard coating layer HC disposed between the support member PG and the adhesive layer AP. The hard coating layer HC may include an acrylic resin.

The hard coating layer HC may reduce irregularities caused by the patterns PP of the folding part FP-P of the support member PG. That is, the hard coating layer HC may provide a flat surface to an upper part of the lower module LM. The hard coating layer HC may be directly disposed on the support member PG.

The hard coating layer HC may have a thickness T₃ of about 1 μm to about 5 μm. When the hard coating layer HC has a thickness T₃ of less than about 1 μm, the hard coating layer HC may not provide a flat surface to the upper surface of the support member PG. When the hard coating layer HC has a thickness T₃ of greater than about 5 μm, there may be a limitation in a folding operation of the electronic device ED.

The hard coating layer HC may have a modulus of about 1000 MPa to about 1500 MPa at −20° C. When the hard coating layer HC has a modulus of less than about 1000 MPa at −20° C., the hard coating layer HC may not provide a flat upper surface to the upper surface of the support member PG. When the hard coating layer HC has a modulus of greater than about 1500 MPa at −20° C., there may be a limitation in a folding operation of the electronic device ED.

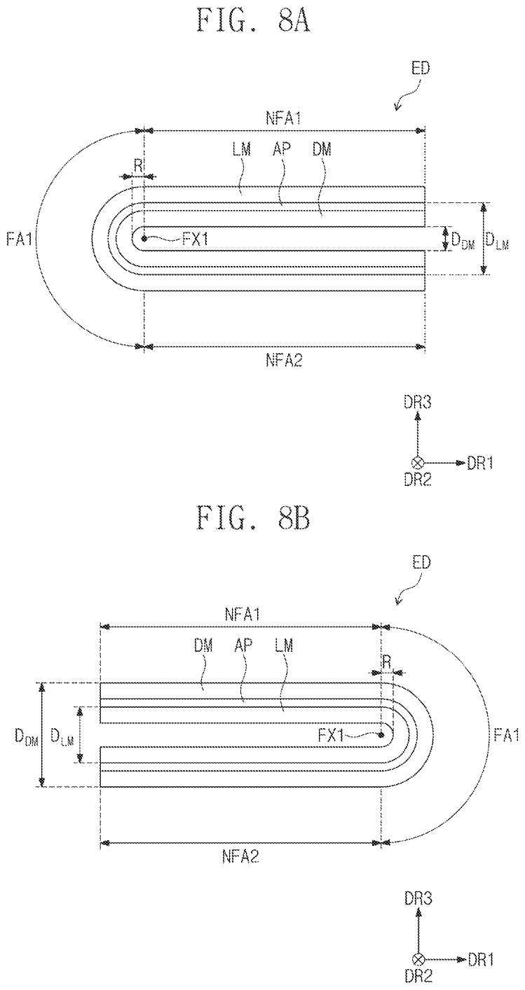

FIGS. 8A and 8B each schematically illustrate a folded electronic device. The following Tables 1 to 8 respectively show evaluation results obtained by simulating impact resistance of the electronic device. The electronic device in an embodiment may be evaluated on the basis of the electronic device illustrated in FIG. 4A and FIG. 8A. Referring to FIGS. 8A and 8B, when the electronic device ED is folded with a curvature radius R of about 1.4, the impact resistance of the electronic device was evaluated according to a strain applied to the encapsulation layer TFE (refer to FIG. 3B) and according to whether buckling occurs in the electronic device in a folded state and in an unfolded state. In an embodiment, a distance DDM between opposite portions of one surface of the display module DM in FIG. 8A may be less than a distance DDM between the opposite portions of the one surface of the display module DM in FIG. 8B, and distance DLM between opposite portions of one surface of the lower module LM in FIG. 8A may be greater than a distance DLM between the opposite portions of the one surface of the lower module LM in FIG. 8B according to the different folding states.

Tables 1 to 4 show that the impact resistance of the electronic device was measured by varying a thickness of the adhesive layer AP (refer to FIG. 4A), a modulus of the adhesive layer AP (refer to FIG. 4A) at μ20° C., a thickness T₃ (refer to FIG. 8A) of the hard coating layer HC (refer to FIG. 8A), and a modulus of the folding part FP-P (refer to FIG. 4A) of the support member PG (refer to FIG. 4A) at −20° C., on the basis of the electronic device in which the support member PG (refer to FIG. 4A) had a thickness T₁, (refer to FIG. 4A) of about 200 μm and the hard coating layer HC (FIG. 8A) had a modulus of about 1300 MPa at −20° C. It was determined that a defect occurred when a strain applied to the encapsulation layer was less than about −0.5. When buckling occurred, it was represented as “NG”; and when buckling did not occur, it was represented as “OK”.

TABLE 1

| | | |
|---|---|---|
| Thickness of Adhesive layer | 15 | μm |
| Modulus of Adhesive layer | 1.1 | MPa |
| at −20° C. | | |
| Thickness of Hard coating layer | 5 | μm |

| Modulus of Folding part | 1 | 100 | 200 | 600 | 800 |
|---|---|---|---|---|---|
| at −20° C. (MPa) | | | | | |
| Strain applied to Encapsulation | 0.49 | 0.3 | 0.13 | −0.41 | −0.62 |
| layer | | | | | |
| Whether Buckling Occurs in | OK | OK | OK | OK | OK |
| Folded state | | | | | |
| Whether Buckling Occurs in | NG | NG | OK | OK | OK |
| Unfolded state | | | | | |

Referring to Table 1, it may be confirmed that in a case where the adhesive layer has a thickness of about 15 μm, the adhesive layer has a modulus of about 1.1 MPa at −20° C., the hard coating layer has a thickness of about 5 μm, and the support member has a thickness of about 200 μm, the strain applied to the encapsulation layer is about −0.5 or more, the buckling does not occur when the support member has a modulus of about 200 MPa to about 800 MPa at −20° C.

TABLE 2

| | | |
|---|---|---|
| Thickness of Adhesive layer | 15 | μm |
| Modulus of Adhesive layer at −20° C. | 2.2 | MPa |
| Thickness of Hard coating layer | 5 | μm |

| Modulus of Folding part at −20° C. (MPa) | 1 | 300 | 500 | 600 |
|---|---|---|---|---|
| Strain applied to Encapsulation layer | 0.5 | — | −0.37 | −0.51 |
| Whether Buckling Occurs in Folded state | OK | NG | OK | OK |
| Whether Buckling Occurs in Unfolded | NG | NG | OK | OK |
| state | | | | |

Referring to Table 2, it may be confirmed that in a case where the adhesive layer has a thickness of about 15 μm, the adhesive layer has a modulus of about 2.2 MPa at −20° C., the hard coating layer has a thickness of about 5 μm, and the support member has a thickness of about 200 μm, the strain applied to the encapsulation layer is about −0.5 or more, the buckling does not occur when the support member has a modulus of about 500 MPa to about 600 MPa at −20° C.

TABLE 3

| | | |
|---|---|---|
| Thickness of Adhesive layer (μm) | 15 | μm |
| Modulus of Adhesive layer at −20° C. | 4.4 | MPa |
| Thickness of Hard coating layer (μm) | 5 | μm |

| Modulus of Folding part at −20° C. (MPa) | 1 | 100 | 400 | 600 |
|---|---|---|---|---|
| Strain applied to Encapsulation layer | 0.51 | 0.29 | −0.28 | −0.6 |
| Whether Buckling Occurs in Folded state | OK | OK | OK | OK |
| Whether Buckling Occurs in Unfolded | NG | OK | OK | OK |
| state | | | | |

Referring to Table 3, it may be confirmed that in a case where the adhesive layer has a thickness of about 15 μm, the adhesive layer has a modulus of about 4.4 MPa at −20° C., the hard coating layer has a thickness of about 5 μm, and the support member has a thickness of about 200 μm, the strain applied to the encapsulation layer is about −0.5 or more, the buckling does not occur when the support member has a modulus of about 100 MPa to about 400 MPa at −20° C.

TABLE 4

| | | |
|---|---|---|
| Thickness of Adhesive layer | 10 | μm |
| Modulus of Adhesive layer | 1300 | MPa |
| at −20° C. | | |

| Thickness of Hard coating layer | — | | | |
|---|---|---|---|---|
| Modulus of Folding part | 1 | 100 | 300 | 600 |
| at −20° C. (MPa) | | | | |
| Strain applied to Encapsulation | 0.63 | 0.39 | −0.06 | −0.66 |
| layer | | | | |
| Whether Buckling Occurs in | OK | OK | OK | OK |
| Folded state | | | | |
| Whether Buckling Occurs in | NG | NG | OK | OK |
| Unfolded state | | | | |

Referring to Table 4, it may be confirmed that in a case where the adhesive layer has a thickness of about 10 μm, the adhesive layer has a modulus of about 1300 MPa at −20° ° C., the hard coating layer is absent, and the support member has a thickness of about 200 μm, the strain applied to the encapsulation layer is about −0.5 or more, the buckling does not occur when the support member has a modulus of about 300 MPa at −20° C.

Tables 5 to 8 show that the impact resistance of the electronic device was measured by varying a thickness T₁ (refer to FIG. 4A) of the support member PG (refer to FIG. 4A) and a modulus of the folding part FP-P (refer to FIG. 4A) of the support member PG (refer to FIG. 4A) at −20° C., on the basis of the electronic device in which the hard coating layer HC (refer to FIG. 8A) had a modulus of 1300 MPa at −20° C., the hard coating layer HC (refer to FIG. 8A) had a thickness T₃ (refer to FIG. 8A) of about 5 μm, the adhesive layer AP had a modulus of about 1.1 MPa at −20° C., and the adhesive layer AP (refer to FIG. 4A) had a thickness T₂ (refer to FIG. 4A) of about 15 μm. It was determined that a defect occurred when a strain applied to the encapsulation layer was less than about −0.5. When buckling occurred, it was represented as “NG”; and when buckling did not occur, it was represented as “OK”.

TABLE 5

| Thickness of Support | 100 μm | | | | |
|---|---|---|---|---|---|
| member | | | | | |
| Modulus of Folding part | 1 | 100 | 200 | 800 | 1000 |
| at −20° C. (MPa) | | | | | |
| Strain applied to | 0.47 | 0.41 | 0.34 | 0.01 | −0.08 |
| Encapsulation layer | | | | | |
| Whether Buckling Occurs | OK | OK | OK | OK | OK |
| in Folded state | | | | | |
| Whether Buckling Occurs | NG | NG | OK | OK | OK |
| in Unfolded state | | | | | |

Referring to Table 5, it may be confirmed that in a case where the support member has a thickness of about 100 μm, and the support member has a modulus of about 200 MPa to about 1000 MPa at −20° C., the strain applied to the encapsulation layer is about −0.5 or more, and the buckling does not occur.

TABLE 6

| Thickness of Support member | 200 μm | | | | |
|---|---|---|---|---|---|
| Modulus of Folding part | 1 | 100 | 200 | 600 | 800 |
| at −20° C. (MPa) | | | | | |
| Strain applied to | 0.49 | 0.3 | 0.13 | −0.41 | −0.62 |
| Encapsulation layer | | | | | |
| Whether Buckling Occurs in | OK | OK | OK | OK | OK |
| Folded state | | | | | |
| Whether Buckling Occurs in | NG | NG | OK | OK | OK |
| Unfolded state | | | | | |

Referring to Table 6, it may be confirmed that in a case where the support member has a thickness of about 200 μm, and the support member has a modulus of about 200 MPa to about 600 MPa at −20° C., the strain applied to the encapsulation layer is about −0.5 or more, and the buckling does not occur.

TABLE 7

| Thickness of Support member | 300 μm | | | |
|---|---|---|---|---|
| Modulus of Folding part | 1 | 100 | 300 | 400 |
| at −20° C. (MPa) | | | | |
| Strain applied to Encapsulation | 0.49 | 0.15 | −0.4 | −0.63 |
| layer | | | | |
| Whether Buckling Occurs in | OK | OK | OK | OK |
| Folded state | | | | |
| Whether Buckling Occurs in | NG | OK | OK | OK |
| Unfolded state | | | | |

Referring to Table 7, it may be confirmed that in a case where the support member has a thickness of about 300 μm, and the support member has a modulus of about 100 MPa to about 300 MPa at −20° C., the strain applied to the encapsulation layer is about −0.5 or more, and the buckling does not occur.

TABLE 8

| Thickness of Support member | 400 μm | | | | |
|---|---|---|---|---|---|
| Modulus of Folding part | 1 | 100 | 200 | 300 | 600 |
| at −20° C. (MPa) | | | | | |
| Strain applied to | 0.49 | −0.03 | −0.46 | −0.83 | 8212 |
| Encapsulation layer | | | | | |
| Whether Buckling Occurs in | OK | OK | OK | OK | NG |
| Folded state | | | | | |
| Whether Buckling Occurs in | NG | NG | OK | OK | NG |
| Unfolded state | | | | | |

Referring to Table 8, it may be confirmed that in a case where the support member has a thickness of about 400 μm, and the support member has a modulus of about 200 MPa to about 300 MPa at −20° C., the strain applied to the encapsulation layer is about −0.5 or more, and the buckling does not occur.

An electronic device in an embodiment includes a support member which is disposed below a display module and includes a folding part having a pattern portion, and an adhesive layer disposed between the support member and the display module. The adhesive layer has a modulus of about 1 MPa or more at −20° C. The electronic device in an embodiment may include the support member including the folding part having the pattern portion, and the adhesive layer having the modulus of about 1 MPa or more at −20° C., thereby exhibiting excellent folding and bending properties and substantially excellent impact resistance.

An electronic device in an embodiment may include a display module, a support member which is disposed below the display module and includes a patterned folding part, and an adhesive member which is disposed between the display module and the support member and has a relatively high modulus, thereby exhibiting good folding property and substantially excellent impact resistance.

Although the embodiments of the inventive concept have been described, it is understood that the inventive concept should not be limited to these embodiments but various changes and modifications may be made by one ordinary skilled in the art within the spirit and scope of the inventive concept as hereinafter claimed.

Therefore, the technical scope of the inventive concept is not limited to the contents described in the detailed description of the specification, but should be determined by the claims.

What is claimed is:

1. An electronic device comprising:
a display module including:
a folding display unit which is foldable with reference to a folding axis extending in a first direction; and
a first non-folding display unit and a second non-folding display unit which are spaced apart from each other with the folding display unit therebetween;
a support member disposed below the display module, and including:
a folding part having a plurality of patterns defined therein and corresponding to the folding display unit; and
a first non-folding part and a second non-folding part respectively corresponding to the first non-folding display unit and the second non-folding display unit; and
an adhesive layer disposed between the display module and the support member,
wherein the adhesive layer has a modulus of about 1 megapascal to about 1500 megapascals at −20 degrees Celsius.

2. The electronic device of claim 1, wherein the adhesive layer is directly disposed on the support member.

3. The electronic device of claim 1, wherein the folding part has a modulus of about 100 megapascals to about 600 megapascals at −20 degrees Celsius.

4. The electronic device of claim 1, wherein the support member has a thickness of about 100 micrometers to about 400 micrometers.

5. The electronic device of claim 1, wherein the adhesive layer has a thickness of about 10 micrometers to about 30 micrometers.

6. The electronic device of claim 1, wherein the support member comprises a first surface adjacent to the display module and a second surface facing the first surface, and
the plurality of patterns comprises a first groove recessed in a direction from the first surface to the second surface and a second groove recessed in the direction from the second surface to the first surface.

7. The electronic device of claim 6, wherein the first groove does not overlap the second groove.

8. The electronic device of claim 6, wherein the first groove and the second groove are alternately arranged in a second direction perpendicular to the first direction.

9. The electronic device of claim 6, further comprising a first resin portion filled in the first groove, and a second resin portion filled in the second groove.

10. The electronic device of claim 9, wherein the first resin portion and the second resin portion each comprise an acrylic resin.

11. The electronic device of claim 1, wherein the plurality of patterns comprises a plurality of openings arranged in a second direction perpendicular to the first direction.

12. The electronic device of claim 11, wherein the plurality of openings comprises first sub-openings arranged in the first direction and second sub-openings spaced apart from the first sub-openings in the second direction perpendicular to the first direction and arranged in the first direction.

13. The electronic device of claim 1, wherein the support member is a glass substrate.

14. The electronic device of claim 1, further comprising a hard coating layer disposed between the support member and the adhesive layer.

15. The electronic device of claim 14, wherein the hard coating layer has a thickness of about 1 micrometer to about 5 micrometers.

16. The electronic device of claim 14, wherein the hard coating layer has a modulus of about 1000 megapascals to about 1500 megapascals at −20 degrees Celsius.

17. The electronic device of claim 14, wherein the hard coating layer is directly disposed on the support member, and
the adhesive layer is directly disposed on the hard coating layer.

18. The electronic device of claim 1, wherein the support member has a thickness of about 100 micrometers to about 400 micrometers, and the folding part has a modulus of about 100 megapascals to about 600 megapascals at −20 degrees Celsius.

19. The electronic device of claim 1, wherein the adhesive layer has a thickness of about 10 micrometers to about 30 micrometers, and the support member has a thickness of about 100 micrometers to about 400 micrometers.

20. The electronic device of claim 1, wherein the support member has a thickness of about 100 micrometers to about 400 micrometers,
the folding part has a modulus of about 100 megapascals to about 600 megapascals at −20 degrees Celsius, and
the adhesive layer has a thickness of about 10 micrometers to about 30 micrometers.
